(19) United States
(12) Patent Application Publication
(10) Pub. No.: US 2025/0095960 A1
(43) Pub. Date: Mar. 20, 2025

(54) ION IMPLANTATION APPARATUS AND SEMICONDUCTOR DEVICE MANUFACTURING METHOD USING THE SAME

(71) Applicant: SAMSUNG ELECTRONICS CO., LTD., Suwon-si (KR)

(72) Inventor: Sang Woo SEON, Suwon-si (KR)

(73) Assignee: SAMSUNG ELECTRONICS CO., LTD., Suwon-si (KR)

(21) Appl. No.: 18/650,860

(22) Filed: Apr. 30, 2024

(30) Foreign Application Priority Data
Sep. 14, 2023 (KR) 10-2023-0122486
Dec. 14, 2023 (KR) 10-2023-0181374

(51) Int. Cl. H01J 37/317; H01J 37/08; H01L 21/265

(52) U.S. Cl. CPC H01J 37/3171; H01J 37/08; H01L 21/265

(57) ABSTRACT

An ion implantation apparatus includes a process chamber into which a substrate is loaded; an ion generation chamber adjacent to the process chamber in a first direction, wherein the ion generation chamber is configured to generate ions and supply the ions to the process chamber in the first direction; a plasma flood gun (PFG) adjacent to the process chamber in a second direction, wherein the PFG is configured to generate electrons and supply the electrons to the process chamber in the second direction; a PFG cage between the PFG and the process chamber and through which the electrons migrate to the process chamber; and a liner film covering at least a portion of an inner sidewall of the process chamber, wherein the liner film includes a conductive material, and wherein the first direction and the second direction are perpendicular to each other.

### CROSS-REFERENCE TO RELATED APPLICATIONS

This application is based on claims priority under 35 U.S.C. § 119 to Korean Patent Application No. 10-2023-0181374, filed on Dec. 14, 2023, and Korean patent Application No. 10-2023-0122486, filed on Sep. 14, 2023, in the Korean Intellectual Property Office, the disclosures of which are incorporated by reference herein in their entireties.

### BACKGROUND

### 1. Field

The disclosure relates to an ion implantation apparatus and a semiconductor device manufacturing method using the ion implantation apparatus.

### 2. Description of Related Art

Along with thermal diffusion technology, ion implantation technology is one of the process technologies used to introduce impurities into a wafer for manufacturing a semiconductor device. A plasma flood gun (PFG) is provided in an ion implantation apparatus. The PFG generates a large amount of electrons inside the apparatus, and then, emits the electrons toward a positively-charged ion beam. The PFG may reduce or prevent arcing, which may occur on the wafer and may be caused by the positively-charged ion beam, and the PFG may compensate for space charge of the ion beam.

### SUMMARY

Provided is an ion implantation apparatus with improved reliability. Also, provided is a semiconductor device manufacturing method with improved reliability.

Aspects according to the disclosure are not limited to the above-mentioned purpose. Other Aspects and advantages according to the disclosure that are not mentioned may be understood based on following descriptions, and may be more clearly understood based on embodiments according to the disclosure. Further, it will be easily understood that the purposes and advantages according to the disclosure may be realized using means shown in the claims or combinations thereof.

According to an aspect of the disclosure, an ion implantation apparatus includes: a process chamber into which a substrate is loaded, and in which an ion implantation process is performed on the substrate; an ion generation chamber adjacent to the process chamber in a first direction, wherein the ion generation chamber is configured to generate ions and supply the ions to the process chamber in the first direction; a plasma flood gun (PFG) adjacent to the process chamber in a second direction, wherein the PFG is configured to generate electrons and supply the electrons to the process chamber in the second direction; a PFG cage between the PFG and the process chamber and through which the electrons migrate to the process chamber; and a liner film covering at least a portion of an inner sidewall of the process chamber, wherein the liner film includes a conductive material, and wherein the first direction and the second direction are perpendicular to each other.

According to an aspect of the disclosure, an ion implantation apparatus includes: a process chamber into which a substrate is loaded, wherein an ion implantation process of irradiating ions in a first direction toward an upper surface of the substrate is performed in the process chamber, wherein the process chamber includes: a first inner sidewall extending in the first direction and a second direction, a second inner sidewall extending in the first direction and the second direction and facing the first inner sidewall, a third inner sidewall extending in the first direction and a third direction and, a fourth inner sidewall extending in the first direction and the third direction and facing the third inner sidewall; an ion generation chamber adjacent to the process chamber in the first direction, and configured to generate the ions and supply the ions to the process chamber in the first direction; a plasma flood gun (PFG) spaced apart from the third inner sidewall of the process chamber in the second direction, and configured to generate electrons and supply the electrons to the process chamber in the second direction; a PFG cage between the third inner sidewall of the process chamber and the PFG, and through which the electrons migrate to the process chamber; and a pair of liner films covering at least a portion of at least one of the first inner sidewall, the second inner sidewall, and the third inner sidewall of the process chamber, wherein the pair of liner films are spaced apart from each other in the third direction and face each other in the third direction, and wherein a surface of the pair of liner films has at least one of a hatched pattern, a checkered pattern, and a dot pattern.

According to an aspect of the disclosure, a method for manufacturing a semiconductor device, includes: loading a substrate into an ion implantation apparatus; and performing an ion implantation process on the substrate, wherein the ion implantation apparatus includes: a process chamber into which a substrate is loaded, and in which the ion implantation process is performed on the substrate; an ion generation chamber adjacent to the process chamber in a first direction, wherein the ion generation chamber is configured to generate ions and supply the ions to the process chamber in the first direction; a plasma flood gun (PFG) adjacent to the process chamber in a second direction, wherein the PFG is configured to generate electrons and supply the electrons to the process chamber in the second direction; a PFG cage between the PFG and the process chamber and through which the electrons migrate to the process chamber; and a liner film covering at least a portion of an inner sidewall of the process chamber, wherein the liner film includes a conductive material, wherein the first direction and the second direction is perpendicular to each other.

Specific details of other embodiments are included in the detailed descriptions and drawings.

### BRIEF DESCRIPTION OF DRAWINGS

The above and other aspects and features of the disclosure will become more apparent by describing in detail some embodiments thereof with reference to the attached drawings, in which:

FIG. 1 and FIG. 2 are example cross-sectional views for illustrating an ion implantation apparatus according to some embodiments;

FIG. 3 is an enlarged view of a P area in FIG. 1;

FIG. 4 is an enlarged view of a Q area in FIG. 2;

FIG. 5 is a perspective view for illustrating a liner film in FIG. 1 and FIG. 2;

FIG. 6 is an example view for illustrating the plasma flood gun (PFG) in FIG. 1;

FIG. 7 to FIG. 11 are plan views to illustrate the liner film of FIG. 1 and FIG. 2;

FIGS. 12 to 18 illustrate an ion implantation apparatus according to some further embodiments of the disclosure; and

FIG. 19 illustrates the semiconductor device manufacturing method according to some embodiments of the disclosure.

### DETAILED DESCRIPTIONS

Although the terms first, second, etc. may be used herein to describe various elements or components, these elements or components should not necessarily be limited by these terms. These terms are used to distinguish one element or component from another element or component. Thus, a first element or component discussed below could be termed a second element or component without departing from the teachings of the disclosure.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

Before undertaking the detailed description below, it may be advantageous to set forth definitions of certain words and phrases used throughout the disclosure. The term “couple” and the derivatives thereof refer to any direct or indirect communication between two or more elements, whether or not those elements are in physical contact with each other. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

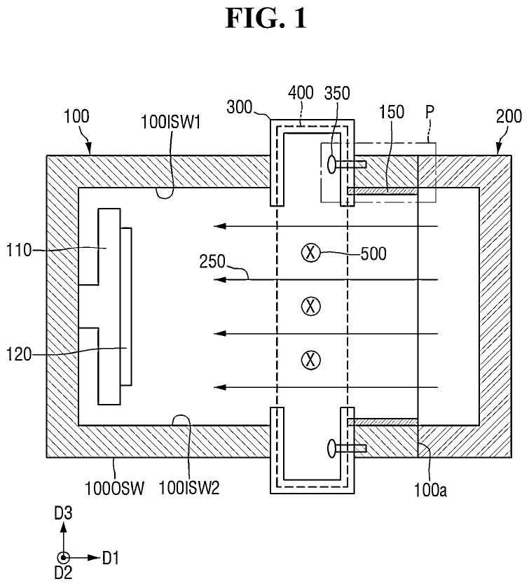

First, referring to FIGS. 1 to 6, an ion implantation apparatus according to some embodiments of the disclosure will be described.

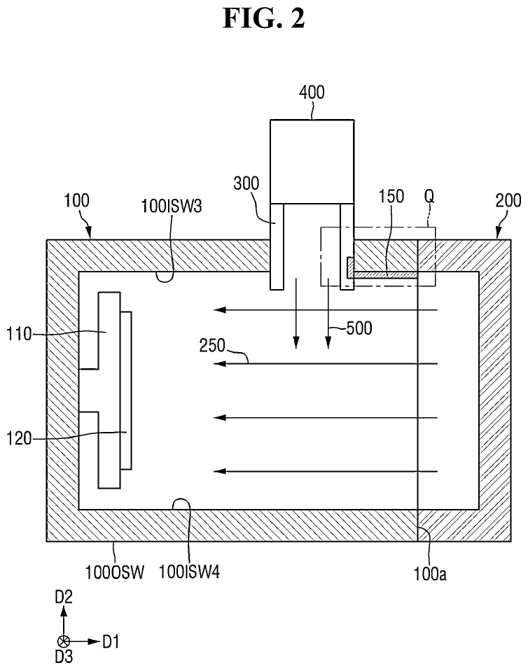

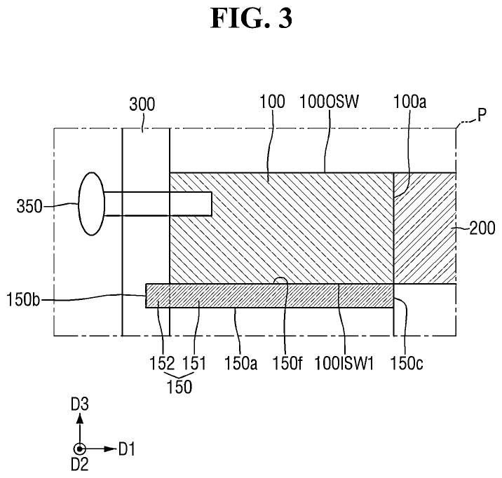

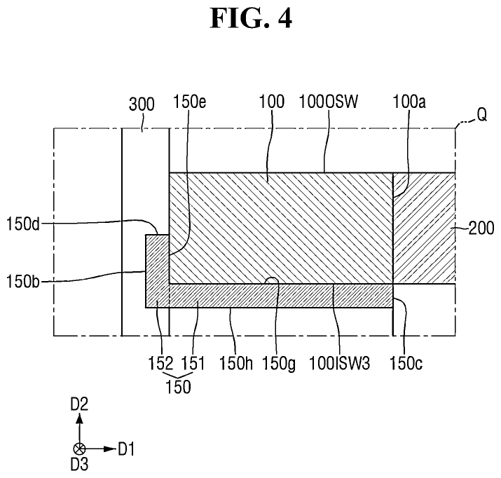

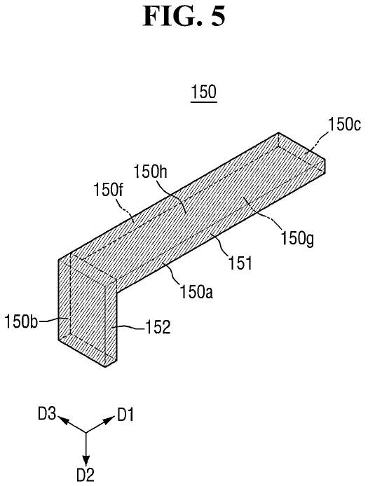

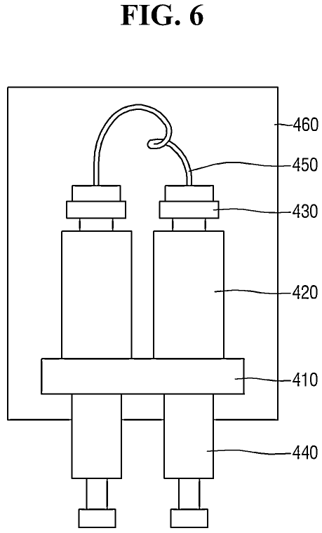

FIG. 1 and FIG. 2 are example cross-sectional views for illustrating an ion implantation apparatus according to some embodiments. FIG. 3 is an enlarged view of a P area in FIG. 1. FIG. 4 is an enlarged view of a Q area in FIG. 2. FIG. 5 is a perspective view for illustrating a liner film in FIG. 1 and FIG. 2. FIG. 6 is an example view for illustrating a plasma flood gun (PFG) in FIG. 1.

First, referring to FIG. 1 and FIG. 2, the ion implantation apparatus according to some embodiments may include a process chamber 100, an ion generation chamber 200, and a PFG 400, a PFG cage 300, and a liner film 150.

In the process chamber 100, an ion implantation process is performed on a substrate 120. The ion generation chamber 200 may generate ions and supply an ion beam to the process chamber 100.

Gas may be supplied into the ion generation chamber 200. For example, the gas may be xenon (Xe) gas. Furthermore, a high frequency wave may be supplied into the ion generation chamber 200. Plasma may be generated by ionizing the xenon gas under high-frequency discharge.

The ion generation chamber 200 may be disposed on one side of the process chamber 100. For example, the ion generation chamber 200 may be disposed adjacent to the process chamber 100 in a first direction D1. That is, the ion generation chamber 200 may supply the ions generated within the ion generation chamber 200 to the process chamber 100 in the first direction D1 (see the reference numeral 250 in FIG. 1).

As used herein and shown in FIG. 1, the first direction D1, a second direction D2, and a third direction D3 may intersect each other. The first direction D1, the second direction D2, and the third direction D3 may be substantially perpendicular to each other. Specifically, the first direction D1 may be perpendicular to an upper surface of the substrate 120. The second direction D2 and the third direction D3 may be parallel to the upper surface of the substrate 120.

In some embodiments, a substrate support unit 110 may be disposed inside the process chamber 100. The substrate support unit 110 may be installed on a portion extending in the third direction D3 and the second direction D2 of an inner sidewall of the process chamber 100. The substrate support unit 110 may be spaced apart from the ion generation chamber 200. That is, the portion of the inner sidewall of the process chamber 100 (on which the substrate support unit 110 is installed) may face the ion generation chamber 200, as shown in FIG. 1.

The substrate support unit 110 may support the substrate 120, as shown in FIG. 1. The substrate support unit 110 may include an electrostatic chuck configured to support the substrate 120 with electrostatic force and a chuck support supporting the electrostatic chuck. The electrostatic chuck may receive an electrode for chucking the substrate 120 on the substrate support unit 110 or de-chucking the substrate 120 from the substrate support unit 110. The chuck support supports the electrostatic chuck disposed on a top of the substrate support unit 110, and may be made of a metal such as aluminum or a ceramic insulator such as alumina. A heating member (such as a heater) may be disposed inside the chuck support, and heat from the heater may be transferred to the electrostatic chuck or the substrate 120. Furthermore, in an embodiment, a power application wire connected to the electrode of the electrostatic chuck may be disposed in the chuck support. A configuration of the substrate support unit 110 is not limited thereto. In some embodiments, the substrate support unit 110 may include a vacuum chuck configured to support the substrate 120 using a vacuum, or may be configured to mechanically support the substrate 120.

In an embodiment, the substrate support unit 110 may include lift pins. The lift pins may be configured to raise up the substrate 120 from a surface of the substrate support unit 110 on which the substrate 120 is seated. Each of the lift pins may be accommodated in a hole provided in the substrate support unit 110. The lift pins may be installed to be movable in a direction perpendicular to the substrate support unit 110. That is, the lift pins may be installed to be movable in the first direction D1.

In an embodiment, the lift pins may move in the first direction D1 to raise or lower the substrate 120. The substrate support unit 110 may include a number of lift pins sufficient to support the substrate 120. For example, the substrate support unit 110 may include three or more lift pins evenly spaced from each other and arranged along a circumferential direction of the substrate support unit 110. However, embodiments of the disclosure are not limited thereto.

When the substrate 120 to be processed is brought into the process chamber 100 or the substrate 120 is taken out from the process chamber 100, the lift pin may be brought into a pin-up state in which the lift pin protrudes from the substrate support unit 110 in the first direction D1 such that the substrate 120 may be supported on the lift pin. Furthermore, while the substrate 120 is being processed in the process chamber 100, the lift pin may be brought into a pin-down state in which the lift pin is positioned at a vertical level lower than that of an upper surface of the substrate support unit 110 in the first direction D1 such that the substrate 120 may be disposed on the substrate support unit 110.

The PFG cage 300 may be disposed on one side of the process chamber 100. Specifically, the PFG cage 300 may be adjacent to the process chamber 100 in the second direction D2. The PFG cage 300 may be interposed between the PFG 400 and the process chamber 100. The PFG cage 300 may have a cylindrical shape with an empty area defined in the cylindrical shape. The empty area of the PFG cage 300 may be used as a channel, thus electrons generated from the PFG 400 (which will be described later) may migrate through the empty area of the PFG cage 300 to the process chamber 100. The electrons generated from the PFG 400 may be supplied to the process chamber 100 in the second direction D2 (see the reference numeral 500 in FIG. 1).

In some embodiments, the process chamber 100 may include an inner sidewall and an outer sidewall 1000SW. The inner sidewall may include a first inner sidewall 100ISW1, a second inner sidewall 100ISW2, a third inner sidewall 100ISW3, and a fourth inner sidewall 100ISW4.

In FIG. 1, the first inner sidewall 100ISW1 and the second inner sidewall 100ISW2 may face each other. The first inner sidewall 100ISW1 and the second inner sidewall 100ISW2 may be spaced apart from each other in the third direction D3. Each of the first inner sidewall 100ISW1 and the second inner sidewall 100ISW2 may be disposed on a plane extending in the first direction D1 and the second direction D2.

In FIG. 2, the third inner sidewall 100ISW3 and the fourth inner sidewall 100ISW4 may face each other. The third inner sidewall 100ISW3 and the fourth inner sidewall 100ISW4 may be spaced apart from each other in the second direction D2. Each of the third inner sidewall 100ISW3 and the fourth inner sidewall 100ISW4 may be disposed on a plane extending in the first direction D1 and the third direction D3.

Each of the first inner sidewall 100ISW1 and the second inner sidewall 100ISW2 may be perpendicular to the third inner sidewall 100ISW3. Each of the first inner sidewall 100ISW1 and the second inner sidewall 100ISW2 may be perpendicular to the fourth inner sidewall 100ISW4. Conversely, each of the third inner sidewall 100ISW3 and the fourth inner sidewall 100ISW4 may be perpendicular to the first inner sidewall 100ISW1. Each of the third inner sidewall 100ISW3 and the fourth inner sidewall 100ISW4 may be perpendicular to the second inner sidewall 100ISW2.

In some embodiments, a portion of the third inner sidewall 100ISW3 may be open. That is, a portion of the process chamber 100 may be open. Electrons generated from the PFG 400 may migrate through an open area into the process chamber 100. The PFG cage 300 may be installed in the open portion of the third inner sidewall 100ISW3. However, the embodiments of the disclosure are not limited thereto.

In some embodiments, a portion of the first inner sidewall 100ISW1 and a portion of the second inner sidewall 100ISW2 may be open to receive the PFG cage 300 in the portion of the first inner sidewall 100ISW1 and the portion of the second inner sidewall 100ISW2. That is, a width of the PFG cage 300 in the third direction D3 may be greater than a distance in the third direction D3 between the first inner sidewall 100ISW1 and the second inner sidewall 100ISW2. However, the embodiments of the disclosure are not limited thereto.

In FIG. 3 and FIG. 4, the liner film 150 may be configured to cover at least a portion of the inner sidewall of the process chamber 100. At least a portion of the liner film 150 may be disposed in the PFG cage 300, and the other portion of the liner film 150 may cover a portion of the inner sidewall of the process chamber 100. The liner film 150 may be provided as a pair of liner films. For example, one of the pair of liner films 150 may cover at least a portion of each (or at least one) of the first inner sidewall 100ISW1 and the third inner sidewall 100ISW3 of the process chamber 100. The other of the pair of liner films 150 may cover a portion of the second inner sidewall 100ISW2 of the process chamber 100. However, the embodiments of the disclosure are not limited thereto.

In some embodiments, the liner film 150 may include a first portion 151 and a second portion 152. The first portion 151 may extend in the first direction D1 and the third direction D3. The second portion 152 may be connected to the first portion 151. The second portion 152 may protrude in the second direction D2. The first portion 151 may cover at least a portion of the inner sidewall of the process chamber 100. That is, one of the pair of first portions 151 may cover at least a portion of each (or at least one) of the first inner sidewall 100ISW1 and the third inner sidewall 100ISW3 of the process chamber 100. The other of the pair of first portions 151 may cover at least a portion of the second inner sidewall 100ISW2 of the process chamber 100.

A first portion of the liner film 150 covering the portion of each of the first inner sidewall 100ISW1 and the third inner sidewall 100ISW3 and a second portion of the liner film 150 covering the portion of the second inner sidewall 100ISW2 may be substantially identical with each other. Hereinafter, the first portion of the liner film 150 covering the portion of each of the first inner sidewall 100ISW1 and the third inner sidewall 100ISW3 will be described.

In some embodiments, at least a portion of the liner film 150 may be disposed in the PFG cage 300. For example, as shown in FIG. 3, the second portion 152 of the liner film 150 may be disposed in the PFG cage 300. That is, the process chamber 100 and the second portion of the liner film 150 may be in direct contact with each other, and the PFG cage 300 and the second portion of the liner film 150 may be in direct contact with each other. Furthermore, at least a portion of the PFG cage 300 may be in direct contact with the process chamber 100.

In some embodiments, the liner film 150 may include a first surface 150a, a second surface 150b, a third surface 150c, a fourth surface 150d, a fifth surface 150e, a sixth surface 150f, a seventh surface 150g, and an eighth surface 150h. FIG. 3 illustrates examples of the first surface 150a, the second surface 150b, the third surface 150c, and the sixth surface 150f, and FIG. 4 illustrates examples of the second surface 150b, the third surface 150c, the fourth surface 150d, the fifth surface 150e, the seventh surface 150g, and the eighth surface 150h. Also, FIG. 5 illustrates examples of the first surface 150a, the second surface 150b, the third surface 150c, the sixth surface 150f, the seventh surface 150g, and the eighth surface 150h.

The first surface 150a may extend in the first direction D1 and the third direction D3. The first surface 150a may be a lower surface of the first portion 151 and the second portion 152. The first surface 150a may be exposed to ions supplied to the process chamber 100. The first surface 150a may be flat. However, the embodiments of the disclosure are not limited thereto. The first surface 150a may not protrude from a lower surface of the PFG cage 300. The lower surface of the PFG cage 300 may protrude from the first surface 150a. That is, the first surface 150a and the lower surface of the PFG cage 300 may not be coplanar with each other.

The second surface 150b may extend in the second direction D2 and the third direction D3. The second surface 150b may be a side surface of the second portion 152. The second surface 150b may be disposed in the PFG cage 300. The second surface 150b may be in direct contact with the PFG cage 300.

The third surface 150c may extend in the second direction D2 and the third direction D3. The third surface 150c may be a side surface of the first portion 151. The third surface 150c may be opposite to the second surface 150b. The third surface 150c may not protrude from one side wall 100a of the process chamber 100. One side wall 100a of the process chamber 100 may be a surface at the process chamber 100 and the ion generation chamber 200 are in direct contact with each other. The third surface 150c may be coplanar with one side wall 100a of the process chamber 100. That is, the third surface 150c and one side wall 100a of the process chamber 100 may constitute the same plane as a plane extending in the second direction D2 and the third direction D3.

The fourth surface 150d may extend in the third direction D3 and the first direction D1. The fourth surface 150d may be an upper surface of the second portion 152. The fourth surface 150d may be opposite to the first surface 150a. The fourth surface 150d may contact (at least a portion of) the PFG cage 300. The fourth surface 150d may not protrude from the outer sidewall 1000SW of the process chamber 100. That is, the second portion 152 may not protrude from the outer sidewall 1000SW of the process chamber 100. At least the portion of the second portion 152 may not overlap the process chamber 100 in the first direction D1. A distance from the first inner sidewall 100ISW1 of the process chamber 100 to the fourth surface 150d may be smaller than a distance from the first inner sidewall 100ISW1 of the process chamber 100 to the outer sidewall 1000SW of the process chamber 100.

The fifth surface 150e may extend in the second direction D2 and the third direction D3. The fifth surface 150e may be a side surface of the second portion 152. The fifth surface 150e may be opposite to the second surface 150b. The fifth surface 150e may be in direct contact with the process chamber 100.

The sixth surface 150f may extend in the first direction D1 and the third direction D3. The sixth surface 150f may be an upper surface of the first portion 151. The sixth surface 150f may be opposite to the first surface 150a. The sixth surface 150f may directly contact the first inner sidewall 100ISW1 of the process chamber 100.

The seventh surface 150g may extend in the first direction D1 and the second direction D2. The seventh surface 150g may be a side surface of the first portion 151. The seventh surface 150g may be in direct contact with the third inner sidewall 100ISW3 of the process chamber 100.

The eighth surface 150h may extend in the first direction D1 and the second direction D2. The eighth surface 150h may be a side surface of the first portion 151. The eighth surface 150h may be exposed to ions supplied to the process chamber 100. The eighth surface 150h may be flat. However, the embodiments of the disclosure are not limited thereto.

In some embodiments, the liner film 150 may include a conductive material. For example, the liner film 150 may include a graphite material. Because the liner film 150 includes a conductive material, the process chamber 100 may be maintained in a ground state. In some embodiments, a specific resistance of the liner film 150 may be substantially the same as that of carbon (C). In another example, the specific resistance of the liner film 150 may be lower than that of carbon (C). For example, the specific resistance of the liner film 150 may be 3.5*10⁻⁵Ω·m, but is not limited thereto.

According to some embodiments, the ion implantation apparatus may further include a fastener 350 that may couple the PFG cage 300 with the process chamber 100. For example, the fastener 350 may pass through the PFG cage 300 and be coupled to the process chamber 100.

Referring to FIG. 6, the PFG 400 may include a support plate 410, an upper body 420, a connection pin 430, a filament fixing member 440, a filament 450, and a case body 460.

The support plate 410, the upper body 420, the connection pin 430, the filament fixing member 440, and the filament 450 may be accommodated in the case body 460. A portion of the case body 460 may be coupled to the PFG cage 300. However, the embodiments of the disclosure are not limited thereto.

The filament 450 may emit electrons. The filament 450 may emit the electrons and supply the electrons to the process chamber 100 (see the reference numeral 500). Electrons may be supplied in the second direction D2. The filament 450 may be inserted into the connection pin 430. The connection pin 430 may have a groove (defined in the connection pin 430) into which an end of the filament 450 may be inserted.

The support plate 410 may be disposed at a lower position in the case body 460. The support plate 410 may support the upper body 420 and the filament fixing member 440. In an embodiment, the support plate 410 may be coupled to and fixed to the case body 460. The support plate 410 may be coupled to the case body 460 and may be firmly fixed thereto. The upper body 420 may be disposed on an upper surface of the support plate 410. The filament fixing member 440 may be disposed on a lower surface of the support plate 410. That is, the upper body 420 and the filament fixing member 440 may be opposite to each other and the support plate 410 is disposed between the upper body 420 and the filament fixing member 440.

The upper body 420 may be provided on the support plate 410. The connection pin 430 may be provided on the upper body 420. In an embodiment, the connection pin 430 may be a pin for fixing the filament 450. The upper body 420 and the support plate 410 may be referred to as an insulator of the PFG. However, the embodiments of the disclosure are not limited thereto.

In some embodiments, there may be two upper bodies 420. The two upper bodies 420 may be spaced apart from each other. In another embodiment, sidewalls of the two upper bodies 420 facing each other may be spaced closely apart from each other. In this regard, the side walls of the upper bodies 420 facing each other may contact each other. When the two upper bodies 420 contact each other, a position of the PFG 400 may be fixed more precisely.

The filament fixing member 440 may be disposed on the lower surface of the support plate 410. The filament 450 may be fixed using the filament fixing member 440. For example, the filament 450 may be fixed to the connection pin 430 and the upper body 420 by rotating the filament fixing member 440.

The PFG 400 may emit a large amount of electrons when the ion implantation apparatus operates. The emitted large amount of electrons may be referred to as emission current. According to some embodiments, the ion implantation apparatus further includes the liner film 150. Since the liner film 150 covers a portion of the inner sidewall of the process chamber 100, a magnitude of the emission current of the PFG 400 may not decrease. Accordingly, the ion implantation apparatus with improved reliability may be provided.

Hereinafter, an ion implantation apparatus according to some further embodiments of the disclosure will be described with reference to FIGS. 6 to 15.

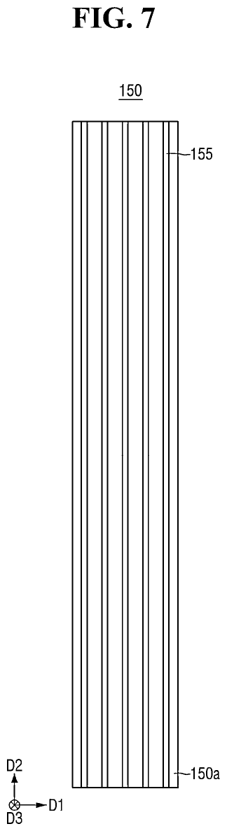

First, referring to FIGS. 7 to 18, the liner film according to some further embodiments of the disclosure is described. FIG. 7 to FIG. 11 are plan views to illustrate the liner film of FIG. 1 and FIG. 2.

First, referring to FIG. 7, the liner film 150 may include a protrusion 155. The protrusion 155 may be disposed on the first surface 150a. The protrusion 155 may protrude from the first surface 150a toward the second inner sidewall 100ISW2 in the third direction D3. As the protrusion 155 is included in the liner film, a surface area size of the liner film 150 exposed to ions may be increased. Accordingly, the ion implantation apparatus with improved reliability may be provided.

The protrusion 155 (of the liner film 150) may extend in an elongate manner in the second direction D2. The protrusion 155 may include at least one protrusion. The protrusions 155 may be spaced apart from each other in the first direction D1. That is, the first surface 150a of the liner film 150 may have a stripe pattern.

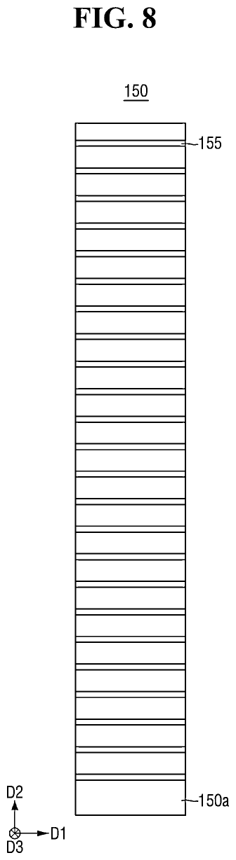

Referring to FIG. 8, the liner film 150 may include the protrusion 155. The protrusion 155 may be disposed on the first surface 150a. The protrusion 155 may protrude from the first surface 150a toward the second inner sidewall 100ISW2 in the third direction D3.

The protrusion 155 may extend in the first direction D1. The protrusion 155 may include at least two protrusion portions. In an embodiment, the at least two protrusion portions of the protrusions 155 may be spaced apart from each other in the second direction D2. That is, the first surface 150a of the liner film 150 may have a stripe pattern.

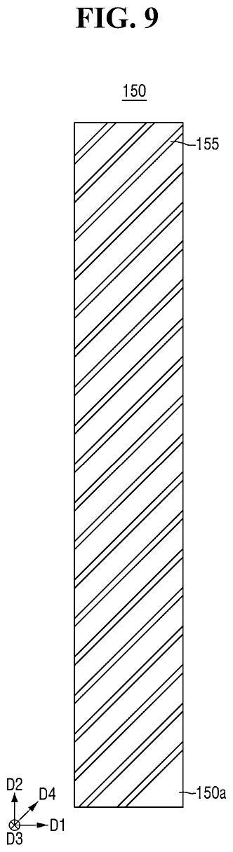

Referring to FIG. 9, the liner film 150 may include the protrusion 155. The protrusion 155 may be disposed on the first surface 150a. The protrusion 155 may protrude from the first surface 150a toward the second inner sidewall 100ISW2 in the third direction D3.

The protrusion 155 may extend in a fourth direction D4 (shown in FIG. 9). The fourth direction D4 may be any direction that intersects the first direction D1 and the second direction D2 in a plane defined by the first direction D1 and the second direction D2. That is, the protrusion 155 may extend in a diagonal direction. In an embodiment, the protrusion 155 may include at least one protrusion. That is, the first surface 150a of the liner film 150 may have a hatched pattern.

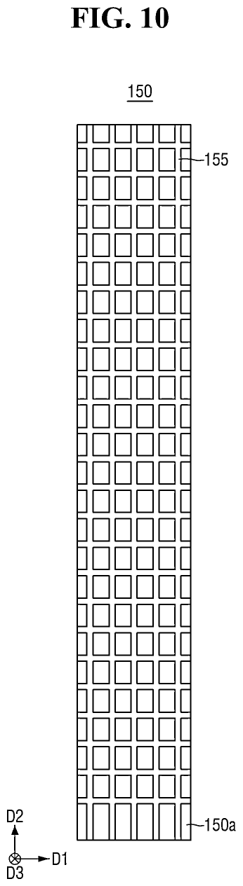

Referring to FIG. 10, the liner film 150 may include the protrusion 155. The protrusion 155 may be disposed on the first surface 150a. The protrusion 155 may protrude from the first surface 150a toward the second inner sidewall 100ISW2 in the third direction D3.

The protrusion 155 may have a grid shape extending in the first direction D1 and the second direction D2. That is, the first surface 150a of the liner film 150 may have a checkered pattern.

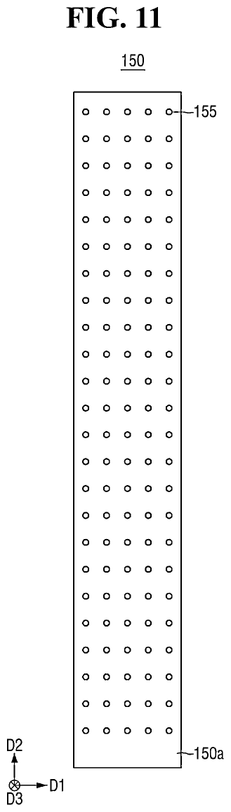

Referring to FIG. 11, the liner film 150 may include the protrusion 155. The protrusion 155 may be disposed on the first surface 150a. The protrusion 155 may protrude from the first surface 150a toward the second inner sidewall 100ISW2 in the third direction D3.

The protrusion 155 may have a circular shape in a plan view. That is, the first surface 150a of the liner film 150 may have a dot pattern.

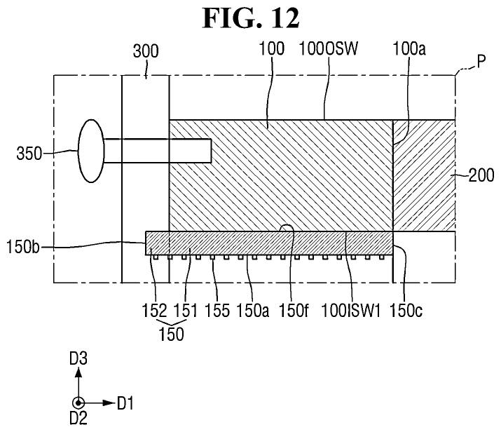

Hereinafter, with reference to FIGS. 12 to 18, an ion implantation apparatus according to some further embodiments of the disclosure will be described. Contents duplicate with those described above using FIGS. 1 to 6 will not be described. FIGS. 12 to 18 illustrate an ion implantation apparatus according to some further embodiments of the disclosure.

First, referring to FIG. 12, the liner film 150 may further include the protrusion 155. The protrusion 155 may be disposed on the first surface 150a. The protrusion 155 may protrude in the third direction D3. As described above, as the liner film 150 includes the protrusion 155, the area size of the first surface 150a exposed to the ions may become larger.

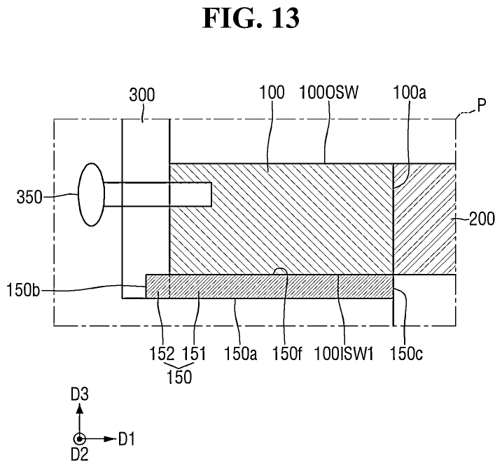

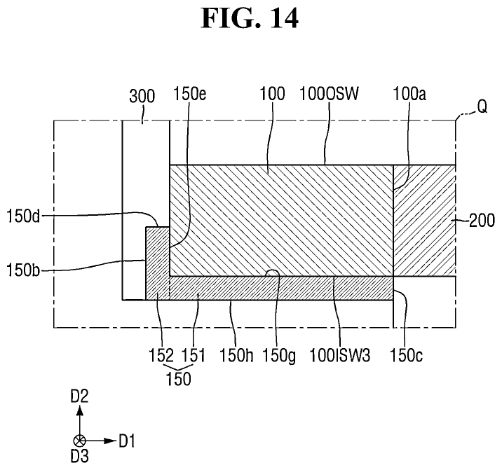

Referring to FIG. 13 and FIG. 14, the PFG cage 300 may not protrude from the second portion 152 of the liner film 150. The lower surface of the PFG cage 300 may be coplanar with the lower surface or the side surface of the second portion 152 of the liner film 150.

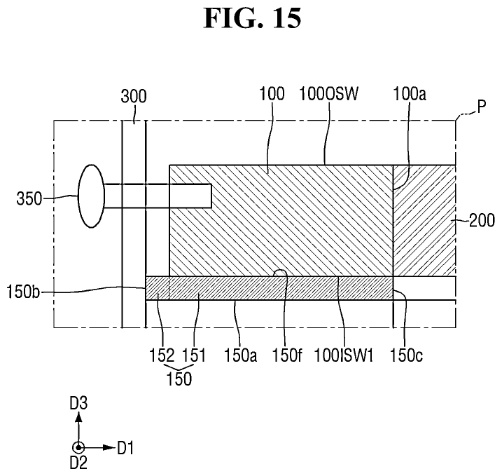

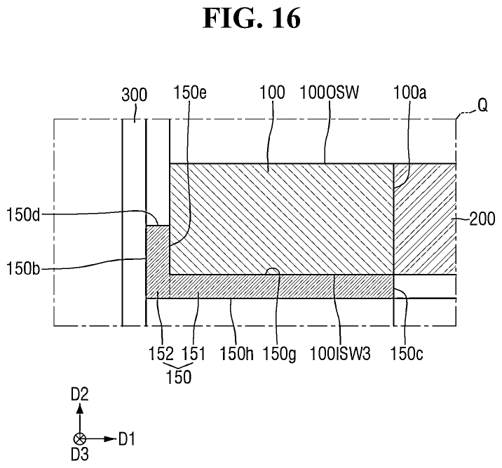

Referring to FIG. 15 and FIG. 16, the second portion 152 of the liner film 150 may not be disposed in the PFG cage 300. Rather, the second portion 152 of the liner film 150 may be interposed between the PFG cage 300 and the process chamber 100. One side wall of the second portion 152 of the liner film 150 may be in direct contact with the PFG cage 300. The other side wall of the second portion 152 of the liner film 150 may be in direct contact with the process chamber 100. The PFG cage 300 and the process chamber 100 may not be in direct contact with each other.

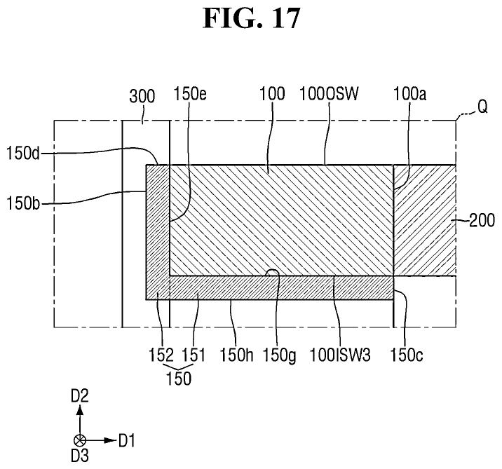

Referring to FIG. 17, the fourth surface 150d of the liner film 150 may be coplanar with the outer sidewall 1000SW of the process chamber 100. In this regard, the second portion 152 of the liner film 150 does not protrude from the outer sidewall 1000SW of the process chamber 100. That is, a height of the fourth surface 150d based on the first inner sidewall 100ISW1 of the process chamber 100 may be the same or substantially same as a height of the outer sidewall 1000SW of the process chamber 100 based on the first inner sidewall 100ISW1 of the process chamber 100. Furthermore, the second portion 152 of the liner film 150 may entirely (or substantially) overlap the process chamber 100 in the first direction D1.

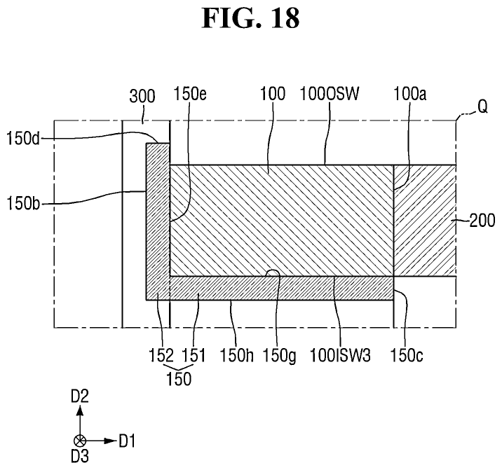

Referring to FIG. 18, the fourth surface 150d of the liner film 150 may protrude from the outer sidewall 1000SW of the process chamber 100 in the third direction D3. At least the second portion 152 of the liner film 150 may protrude from the outer sidewall 1000SW of the process chamber 100 in the third direction D3. That is, at least a portion of the second portion 152 of the liner film 150 may not overlap the process chamber 100 in the first direction D1. Furthermore, the height of the fourth surface 150d based on the first inner sidewall 100ISW1 of the process chamber 100 may be greater than the height of the outer sidewall 1000SW of the process chamber 100 based on the first inner sidewall 100ISW1 of the process chamber 100.

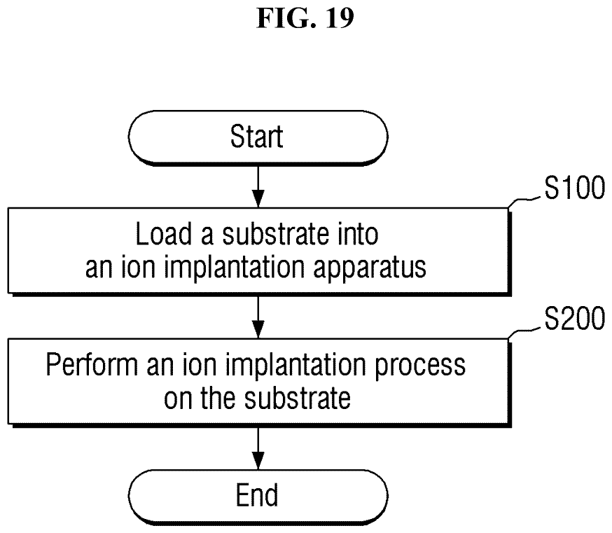

Hereinafter, a semiconductor device manufacturing method according to some embodiments of the disclosure is described. FIG. 19 is a flowchart for illustrating the semiconductor device manufacturing method according to some embodiments of the disclosure.

Referring to FIG. 19, the semiconductor device manufacturing method according to some embodiments may include an operation of loading the substrate into the process chamber in S100 and performing an ion implantation process on the substrate in S200.

Specifically, referring to FIG. 1 and FIG. 19, the substrate 120 may be loaded into the process chamber 100 in S100. The substrate 120 may be loaded on the substrate support unit 110. Subsequently, an ion implantation process may be performed on the substrate 120. First, ions may be generated in the ion generation chamber 200. The ions may be supplied to the process chamber 100 in the first direction D1 (see the reference numeral 250).

For example, at a time when the ions are supplied to the process chamber 100 in the first direction D1, the PFG 400 may generate the electrons and supply the electrons to the process chamber 100. The electrons may be supplied in the second direction D2 (see the reference numeral 500). As the ions are supplied to the process chamber 100, the inner sidewall of the process chamber may be contaminated by the ions. However, according to some embodiments of the disclosure, the ion implantation apparatus of the disclosure includes the liner film 150, thereby preventing contamination of the inner sidewall of the process chamber. Accordingly, the process chamber 100 may be maintained at a ground state. Furthermore, the emission current may not decrease. Accordingly, the ion implantation apparatus with improved reliability may be provided.

Although embodiments of the disclosure have been described with reference to the accompanying drawings, the disclosure is not limited to the above embodiments, but may be implemented in various different forms. A person skilled in the art may appreciate that the disclosure may be practiced in other concrete forms without changing the technical spirit or essential characteristics of the disclosure. Therefore, it should be appreciated that the embodiments as described above is not restrictive but illustrative in all respects.

What is claimed is:

1. An ion implantation apparatus comprising:
a process chamber into which a substrate is loaded, and in which an ion implantation process is performed on the substrate;
an ion generation chamber adjacent to the process chamber in a first direction, wherein the ion generation chamber is configured to generate ions and supply the ions to the process chamber in the first direction;
a plasma flood gun (PFG) adjacent to the process chamber in a second direction, wherein the PFG is configured to generate electrons and supply the electrons to the process chamber in the second direction;
a PFG cage between the PFG and the process chamber and through which the electrons migrate to the process chamber; and
a liner film covering at least a portion of an inner sidewall of the process chamber,
wherein the liner film comprises a conductive material, and
wherein the first direction and the second direction intersect each other.

2. The ion implantation apparatus of claim 1, wherein the liner film comprises a graphite material.

3. The ion implantation apparatus of claim 1, wherein the liner film comprises:
a first portion extending in the first direction and a third direction; and
a second portion connected to the first portion and extending in the second direction, and
wherein the third direction intersects the first and second directions.

4. The ion implantation apparatus of claim 3, wherein the second portion is between the PFG cage and the process chamber.

5. The ion implantation apparatus of claim 3, wherein the second portion is in the PFG cage, and
wherein the PFG cage and the process chamber are in contact with each other.

6. The ion implantation apparatus of claim 3, wherein at least a portion of the second portion protrudes from an outer sidewall of the process chamber.

7. The ion implantation apparatus of claim 1, wherein a surface of the liner film is exposed to the ions, and
wherein the surface of the liner film has at least one of a hatched pattern, a checkered pattern, and a dot pattern.

8. The ion implantation apparatus of claim 1, wherein a resistance of the liner film is equal to a resistance of carbon.

9. An ion implantation apparatus comprising:
a process chamber into which a substrate is loaded, wherein an ion implantation process of irradiating ions in a first direction toward an upper surface of the substrate is performed in the process chamber,
wherein the process chamber comprises:
a first inner sidewall extending in the first direction and a second direction,
a second inner sidewall extending in the first direction and the second direction and facing the first inner sidewall,
a third inner sidewall extending in the first direction and a third direction and,
a fourth inner sidewall extending in the first direction and the third direction and facing the third inner sidewall;
an ion generation chamber adjacent to the process chamber in the first direction, and configured to generate the ions and supply the ions to the process chamber in the first direction;
a plasma flood gun (PFG) spaced apart from the third inner sidewall of the process chamber in the second direction, and configured to generate electrons and supply the electrons to the process chamber in the second direction;
a PFG cage between the third inner sidewall of the process chamber and the PFG, and through which the electrons migrate to the process chamber; and
a pair of liner films covering at least a portion of at least one of the first inner sidewall, the second inner sidewall, and the third inner sidewall of the process chamber,
wherein the pair of liner films are spaced apart from each other in the third direction and face each other in the third direction, and
wherein a surface of the pair of liner films has at least one of a hatched pattern, a checkered pattern, and a dot pattern.

10. The ion implantation apparatus of claim 9, wherein a resistance of one of the pair of liner films is equal to a resistance of carbon.

11. The ion implantation apparatus of claim 9, wherein one of the pair of liner films comprises a conductive material.

12. The ion implantation apparatus of claim 9, wherein one of the pair of liner films comprises:
a first portion extending in the first direction and the third direction; and
a second portion connected to the first portion and extending in the second direction.

13. The ion implantation apparatus of claim 12, wherein the second portion is between the PFG cage and the process chamber.

14. The ion implantation apparatus of claim 12, wherein the second portion is in the PFG cage, and
wherein the PFG cage and the process chamber are in contact with each other.

15. The ion implantation apparatus of claim 12, wherein at least a portion of the second portion protrudes from a sidewall of the process chamber.

16. A method for manufacturing a semiconductor device, the method comprising:
loading a substrate into an ion implantation apparatus; and
performing an ion implantation process on the substrate,
wherein the ion implantation apparatus comprises:
a process chamber into which a substrate is loaded, and in which the ion implantation process is performed on the substrate;
an ion generation chamber adjacent to the process chamber in a first direction, wherein the ion generation chamber is configured to generate ions and supply the ions to the process chamber in the first direction;
a plasma flood gun (PFG) adjacent to the process chamber in a second direction, wherein the PFG is configured to generate electrons and supply the electrons to the process chamber in the second direction;
a PFG cage between the PFG and the process chamber and through which the electrons migrate to the process chamber; and
a liner film covering at least a portion of an inner sidewall of the process chamber,
wherein the liner film comprises a conductive material,
wherein the first direction and the second direction is perpendicular to each other.

17. The method of claim 16, wherein the liner film comprises:
a first portion extending in the first direction and a third direction; and
a second portion connected to the first portion and protruding in the second direction, and
wherein the third direction is perpendicular to the first and second directions.

18. The method of claim 17, wherein the second portion is in the PFG cage, and
wherein the PFG cage and the process chamber are in contact with each other.

19. The method of claim 16, wherein a surface of the liner film is exposed to the ions, and
wherein the surface of the liner film has at least one of a hatched pattern, a checkered pattern, and a dot pattern.

20. The method of claim 16, wherein a resistance of the liner film is equal to a resistance of carbon.
